(19) United States
(12) Patent Application Publication
(10) Pub. No.: US 2006/0289881 A1
(43) Pub. Date: Dec. 28, 2006

(54) SEMICONDUCTOR LIGHT EMITTING DEVICE

(76) Inventors: Yen-Wen Chen, Hsinchu (TW); Wen-Huang Liu, Hsinchu (TW); Wei-Chih Peng, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/308,981

(22) Filed: Jun. 2, 2006

(30) Foreign Application Priority Data
Jun. 24, 2005 (TW) 94121291

(51) Int. Cl. H01L 33/00

(52) U.S. Cl. 257/91

(57) ABSTRACT

A semiconductor light emitting device including a substrate, a semiconductor light emitting stack, a first electrode, a first transparent oxide conductive layer and a second electrode is provided. The semiconductor light emitting stack is disposed on the substrate and has a first surface region and a second surface region. The first electrode is disposed on the first surface region. The first transparent oxide conductive layer is disposed on the second surface region. The second electrode is disposed on the first transparent oxide conductive layer. The area of the light emitting device is larger than 2.5×10⁵ μm², and the distance between the first electrode and the second electrode is between 150 μm and 250 μm essentially, and the area of the first electrode and the second electrode is 15%˜25% of that of the light emitting layer.

### CROSS-REFERENCE TO RELATED APPLICATION

This application claims the priority benefit of Taiwan application serial no. 94121291, filed on Jun. 24, 2005. All disclosure of the Taiwan application is incorporated herein by reference.

### BACKGROUND OF THE INVENTION

1. Technical Field

The present invention relates to a semiconductor light emitting device and in particular to an arrangement of electrodes of the semiconductor light emitting device.

2. Description of the Related Art

Semiconductor light emitting devices have been employed in a wide variety of applications, including optical displays, traffic lights, data storage apparatus, communication devices, illumination apparatus, and medical treatment equipment. How to improve the light emitting efficiency of light emitting devices is an important issue in this art.

In U.S. Pat. No. 5,563,422, an LED (Light Emitting Diode) is disclosed. A thin Ni/Au transparent conductive layer is formed on a p-type contact layer to spread the current, and to further improve the light emitting characteristics of the LED. However, the transmittance of the transparent conductive layer is about 60%˜70%, and the light emitting efficiency of the LED is affected.

To resolve this problem, a transparent oxide conductive layer made of indium tin oxide and the like is used to replace the conventional Ni/Au transparent conductive layer. The transparent oxide conductive layer has a higher transmittance, and therefore most of the light generated from the LED can travel through the transparent oxide conductive layer. Nevertheless, compared with metal, the resistance of the transparent oxide conductive layer is higher, and thus the current spreading effect of the transparent oxide conductive layer is limited when it is applied to a large-sized LED.

In U.S. Pat. No. 6,307,218, an electrode structure for light emitting devices is disclosed to evenly spread the current of the light emitting device by changing the shapes of the devices, the electrodes, or the position of the electrodes. Besides, in U.S. Pat. No. 6,614,056, an LED using the conductive fingers to improve the current spreading is also disclosed. Furthermore, in U.S. Pat. No. 6,518,598, a nitride LED having a spiral electrode is provided. The LED utilizes an etching or polishing method to form a spiral-shaped trench in the surface of the epitaxial structure thereof, so that the two metal electrodes having opposite electrical properties have the spiral-shaped pattern structures in parallel. The LED can evenly distribute the injected current between two spiral-shaped electrodes having opposite electrical properties, to enhance the current-spreading efficiency.

The metal electrodes of the conventional light emitting devices or LEDs absorb light and will reduce the brightness of the LEDs if the metal electrodes have a higher density on the surface of the LEDs. But if the metal electrodes have a lower density on the surface of the LEDs, the effect of current spreading will be decreased, and the driving voltage will be increased. In the event, the light emitting efficiency would be lower. Therefore, how to balance the optimum brightness and better current spreading of LEDs to enhance the light emitting efficiency is an important issue in the technology.

### SUMMARY OF THE INVENTION

Accordingly, the present invention is to provide a semiconductor light emitting device having higher brightness and better current spreading.

As embodied and broadly described herein, the present invention provides a semiconductor light emitting device comprising a substrate, a semiconductor light emitting stack, a first electrode, a first transparent oxide conductive layer and a second electrode. The semiconductor light emitting stack is disposed on the substrate and has a first surface region and a second surface region. The semiconductor light emitting stack comprises a first semiconductor layer, a light emitting layer and a second semiconductor layer. The first semiconductor layer is disposed on the substrate. The light emitting layer is disposed on the first semiconductor layer. The second semiconductor layer is disposed on the light emitting layer. The first electrode is disposed on the first surface region. The first transparent oxide conductive layer is disposed on the second surface region. The second electrode is disposed on the first transparent oxide conductive layer. The area of the light emitting device is larger than 2.5×10⁵ μm², and the distance between the first electrode and the second electrode is between 150 μm and 250 μm essentially, and the area of the first electrode and the second electrode is 15%˜25% of that of the light emitting layer.

According to one embodiment of the present invention, the semiconductor light emitting device further comprises an adhesive layer disposed between the substrate and the semiconductor light emitting stack.

According to one embodiment of the present invention, the adhesive layer comprises at least one material selected from the group consisting of polyimide, benzocyclobutene (BCB), prefluorocyclobutane (PFCB), indium tin oxide, In, Sn, Al, Au, Pt, Zn, Ag, Ti, Pb, Ni, Au—Be, Au—Sn, Au—Si, Pb—Sn, Au—Ge, PdIn, and AuZn.

According to one embodiment of the present invention, the semiconductor light emitting device further comprises a first reactive layer disposed between the substrate and the adhesive layer.

According to one embodiment of the present invention, the first reactive layer comprises at least one material selected from the group consisting of SiNx, titanium, and chromium.

According to one embodiment of the present invention, the semiconductor light emitting device further comprises a reflective layer disposed between the substrate and the first reactive layer.

According to one embodiment of the present invention, the reflective layer comprises at least one material selected from the group consisting of In, Sn, Al, Pt, Zn, Ag, Ti, Pb, Pd, Ge, Cu, AuBe, AuGe, Ni, PbSn, and AuZn.

According to one embodiment of the present invention, the semiconductor light emitting device further comprises a second reactive layer disposed between the light emitting stack and the adhesive layer.

According to one embodiment of the present invention, the second reactive layer comprises at least one material selected from the group consisting of SiNx, titanium, and chromium.

According to one embodiment of the present invention, the semiconductor light emitting device further comprises a reflective layer disposed between the light emitting stack and the second reactive layer.

According to one embodiment of the present invention, the reflective layer comprises at least one material selected from the group consisting of In, Sn, Al, Pt, Zn, Ag, Ti, Pb, Pd, Ge, Cu, AuBe, AuGe, Ni, PbSn, and AuZn.

According to one embodiment of the present invention, the substrate comprises at least one material selected from the group consisting of GaP, SiC, Al₂O₃, GaAs, GaP, AlGaAs, GaAsP, and glass.

According to one embodiment of the present invention, the second surface region of the semiconductor light emitting stack is a highly doped p-type semiconductor contact region, a reverse tunnel region or a surface roughed region.

According to one embodiment of the present invention, the first semiconductor layer comprises at least one material selected from the group consisting of AlN, GaN, AlGaN, InGaN, AlInGaN, GaP, GaAsP, GaInP, AlGaInP, and AlGaAs.

According to one embodiment of the present invention, the light emitting layer comprises at least one material selected from the group consisting of GaN, AlGaN, InGaN, AlInGaN, and AlGaInP.

According to one embodiment of the present invention, the second semiconductor layer comprises at least one material selected from the group consisting of AlN, GaN, AlGaN, InGaN, AlInGaN, GaP, GaAsP, GaInP, AlGaInP, and AlGaAs.

According to one embodiment of the present invention, the shape of the first electrode comprises spiral shape, plane shape, and arborization.

According to one embodiment of the present invention, the shape of the second electrode comprises spiral shape, plane shape, and arborization.

According to one embodiment of the present invention, the first transparent oxide conductive layer comprises at least one material selected from the group consisting of indium tin oxide, cadmium tin oxide, antimony tin oxide, aluminum tin oxide, and zinc tin oxide.

According to one embodiment of the present invention, the semiconductor light emitting stack further comprises a second transparent oxide conductive layer disposed on the second semiconductor layer.

According to one embodiment of the present invention, the second transparent oxide conductive layer comprises at least one material selected from the group consisting of indium tin oxide, cadmium tin oxide, antimony tin oxide, aluminum tin oxide, and zinc tin oxide.

According to one embodiment of the present invention, the second transparent oxide conductive layer has the first surface region.

According to one embodiment of the present invention, the first semiconductor layer has the first surface region.

### BRIEF DESCRIPTION OF THE DRAWINGS

The accompanying drawings are included to provide easy understanding of the invention, and are incorporated herein and constitute a part of this specification. The drawings illustrate embodiments of the invention and, together with the description, serve to illustrate the principles of the invention.

FIG. 1 and FIG. 2 are schematic cross-sectional and top views illustrating a semiconductor light emitting device according to a first embodiment of the present invention respectively.

FIG. 3 is a diagram illustrating a relationship of the brightness and distance between the first and the second electrodes.

FIG. 4 is a diagram illustrating a relationship of the light emitting efficiency and distance between the first and the second electrodes.

FIG. 5 and FIG. 6 are schematic cross-sectional and top views illustrating a semiconductor light emitting device according to a second embodiment of the present invention respectively.

FIG. 7 is a diagram illustrating a relationship of the forward current and the light emitting efficiency of the semiconductor light emitting device.

FIG. 8 is a diagram illustrating a relationship of the proportion between the area of the first and second electrode and that of the light emitting layer and the light emitting efficiency of the semiconductor light emitting device.

FIG. 9 is a schematic cross-sectional view illustrating a semiconductor light emitting device according to a third embodiment of the present invention.

FIG. 10 is a diagram illustrating a relationship of the proportion between the area of the first and second electrode and that of the light emitting layer and the light emitting efficiency of the semiconductor light emitting device.

FIG. 11A and FIG. 11B are schematic top views illustrating different arrangement of the first electrode and the second electrode.

### DESCRIPTION OF THE EMBODIMENTS

Reference will now be made in detail to the preferred embodiments of the present invention, examples of which are illustrated in the accompanying drawings. Wherever possible, the same reference numbers are used in the drawings and the description to refer to the same or like parts.

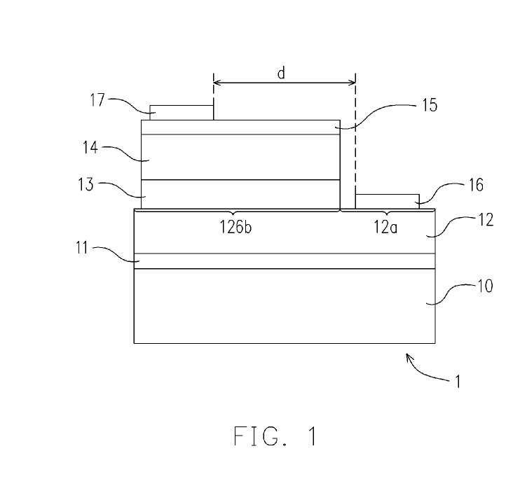

FIG. 1 and FIG. 2 are schematic cross-sectional and top views illustrating a semiconductor light emitting device according to a first embodiment of the present invention respectively. Please refer to FIG. 1 and FIG. 2, the semiconductor light emitting device 1 mainly comprises a substrate 10, a semiconductor light emitting stack, a transparent oxide conductive layer 15, a first electrode 16 and a second electrode 17. The semiconductor light emitting stack comprises a first semiconductor layer 12, a light emitting layer 13 and a second semiconductor layer 14. The substrate comprises at least one material selected from the group consisting of GaP, SiC, Al2O3, GaAs, GaP, AlGaAs, GaAsP, and glass. A buffer layer 11 is selectively disposed on the substrate 10. The first semiconductor layer 12 is disposed on the buffer layer 11 and is a nitride stack having a first surface region 12a and a second surface region 12b. The material of the first semiconductor layer 12 can be AlN, GaN, AlGaN, InGaN, AlInGaN, GaP, GaAsP, GaInP, AlGaInP, or AlGaAs.

The light emitting layer 13 is disposed on the second surface region 12b of the first semiconductor layer 12, and the material of the light emitting layer 13 can be GaN, AlGaN, InGaN, AlInGaN, or AlGaInP. The second semiconductor layer 14 is disposed on the light emitting layer 13 and can be a nitride stack. The material of the nitride stack can be AlN, GaN, AlGaN, InGaN, AlInGaN, GaP, GaAsP, GaInP, AlGaInP, or AlGaAs. The second semiconductor layer 14 of the semiconductor light emitting stack is a highly doped p-type semiconductor contact region, a reverse tunnel region or a surface roughed region. The transparent oxide conductive layer 15 is disposed on the second semiconductor layer 14, and the material of the transparent oxide conductive layer 15 can be indium tin oxide, cadmium tin oxide, antimony tin oxide, aluminum tin oxide and zinc tin oxide. The first electrode 16 is disposed on the first surface region 12a of the first semiconductor layer 12. The second electrode 17 is disposed on the transparent oxide conductive layer 15. As shown in FIG. 2, the first electrode 16 is paralleled to the second electrode 17, and the distance between the first electrode 16 and the second electrode 17 is d. The influence on the brightness and current spreading of the light emitting device 1 resulting from the distance d between the first electrode 16 and the second electrode 17 is illustrated in the following.

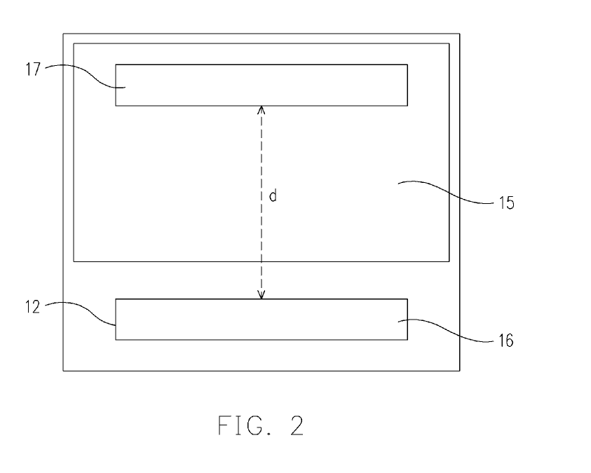

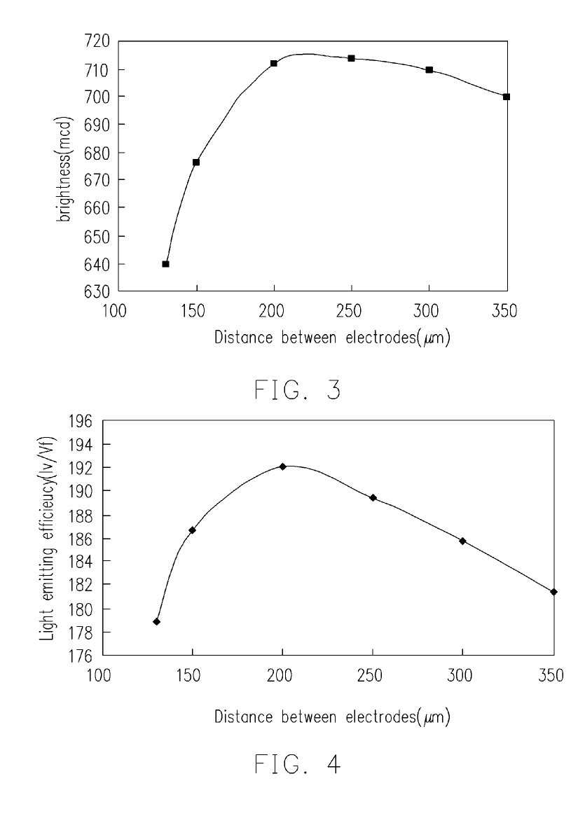

The distance between the first electrode 16 and the second electrode 17 is changed under the conditions that the light emitting device has a constant area of 3×10⁵ μm² (480 μm×640 μm), a constant current of 0.07 A is transmitted to the light emitting device, and the area of the first electrode 16 and the second electrode 17 are both 1.53×10⁴ μm². The variation of brightness, forward bias and light emitting efficiency of the light emitting device are shown in Table 1. FIG. 3 is a diagram illustrating a relationship of the brightness and distance between the first and the second electrodes. As shown in FIG. 3, the brightness increased with the distance of the first electrode and the second electrode from 130 μm to 200 μm. The brightness of the light emitting device is optimum when the distance between the two electrodes is between 200 μm to 250 μm, and it decreased when the distance between the two electrodes is larger than 250 μm. FIG. 4 is a diagram illustrating a relationship of the light emitting efficiency (namely the brightness divided by the forward bias) and distance between the first and the second electrodes. As shown in FIG. 4, the brightness and the light emitting efficiency of the light emitting device 1 is optimum when the distance between the first electrode and the second electrode is between 150 μm and 280 μm.

TABLE 1

| The distance | | | |
|---|---|---|---|
| between the | | | |
| first electrode | | | |
| and the second | Brightness Iv | Forward Bias Vf | Light Emitting |
| electrode (μm) | (mcd) | (V) | Efficiency (Iv/Vf) |
| 350 | 699.7 | 3.85 | 181.74 |
| 300 | 709.5 | 3.79 | 187.2 |
| 250 | 713.4 | 3.72 | 191.77 |
| 200 | 712 | 3.65 | 195.07 |
| 150 | 676.2 | 3.59 | 188.36 |
| 130 | 639.5 | 3.58 | 178.63 |

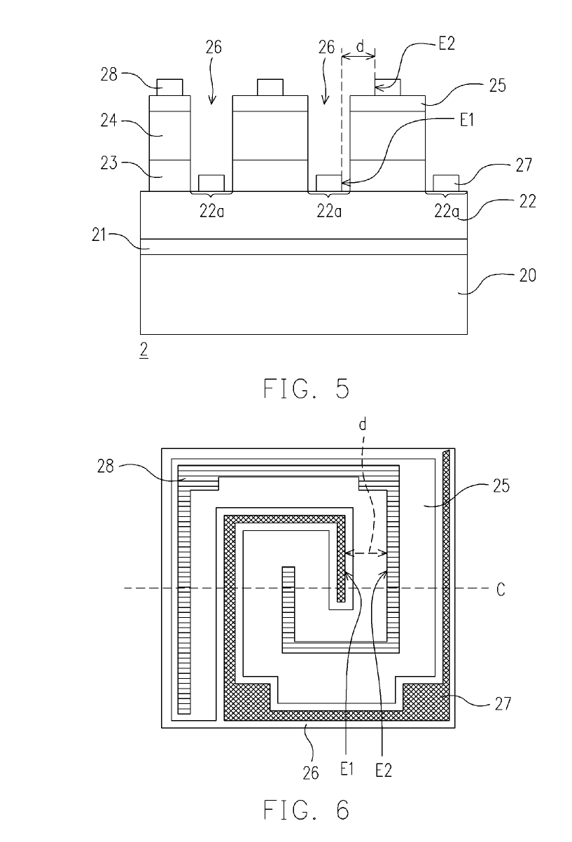

FIG. 5 and FIG. 6 are schematic cross-sectional and top views illustrating a semiconductor light emitting device according to a second embodiment of the present invention respectively. Please refer to FIG. 5 and FIG. 6, the semiconductor light emitting device 2 mainly comprises a substrate 20, a first semiconductor layer 22, a light emitting layer 23, a second semiconductor layer 24, a transparent oxide conductive layer 25, a first electrode 27 and a second electrode 28. A buffer layer 21 is selectively disposed on the substrate 20. The first semiconductor layer 22 is disposed on the buffer layer 21 and can be a nitride stack. The material of the nitride stack can be AlN, GaN, AlGaN, InGaN, AlInGaN, GaP, GaAsP, GaInP, AlGaInP, or AlGaAs. The light emitting layer 23 is disposed on the first semiconductor layer 22, and the material of the light emitting layer 13 can be GaN, AlGaN, InGaN, AlInGaN, or AlGaInP. The second semiconductor layer 24 is disposed on the light emitting layer 23 and can be a nitride stack. The material of the nitride stack can be AlN, GaN, AlGaN, InGaN, AlInGaN, GaP, GaAsP, GaInP, AlGaInP, or AlGaAs. The transparent oxide conductive layer 25 is disposed on the second semiconductor layer 24, and the material of the transparent oxide conductive layer 25 can be indium tin oxide, cadmium tin oxide, antimony tin oxide, aluminum tin oxide, and zinc tin oxide. A spiral groove 26 is formed in the transparent oxide conductive layer 25, the second semiconductor layer 24 and the light emitting layer 23, to expose a portion of the first semiconductor layer 22 and form a first electrode region 22a. The first electrode 27 is disposed on the first electrode region 22a. The second electrode 28 is disposed on the transparent oxide conductive layer 25. As shown in FIG. 6, the first electrode 27 and the second electrode 28 are spiral shape, and the distance between a first edge E1 of the first electrode 27 and a second edge E2 of the second electrode 28 adjacent to the first edge E1 is d. The influence on the brightness and current spreading of the light emitting device 2 resulting from the proportion of the area of the first and second electrode to that of the light emitting layer is illustrated in the following.

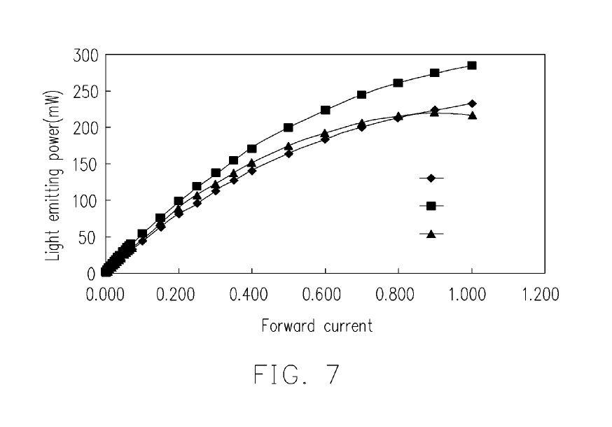

FIG. 7 is a diagram illustrating a relationship of the forward current and the light emitting efficiency of the semiconductor light emitting device. As shown in FIG. 7, under the conditions that the area of the light emitting device is 1×10⁶ μm² (1000 μm×1000 μm), the input current is 350 mA, and the area of the first and second electrode is 24.4% of that of the light emitting layer, if the distance between the first electrode 27 and the second electrode 28 is 130 μm, 166 μm and 210 μm respectively, the light emitting efficiency of the light emitting device of which the distance between the electrodes is 166 μm and 210 μm is higher than that of the light emitting device of which the distance between the electrodes is 130 μm. However, the forward bias increases with the increasing distance between the electrodes. Besides, from the experiment data of the first embodiment, the forward bias can be adjusted by changing the area of the first and second electrode to solve the problem of higher forward bias.

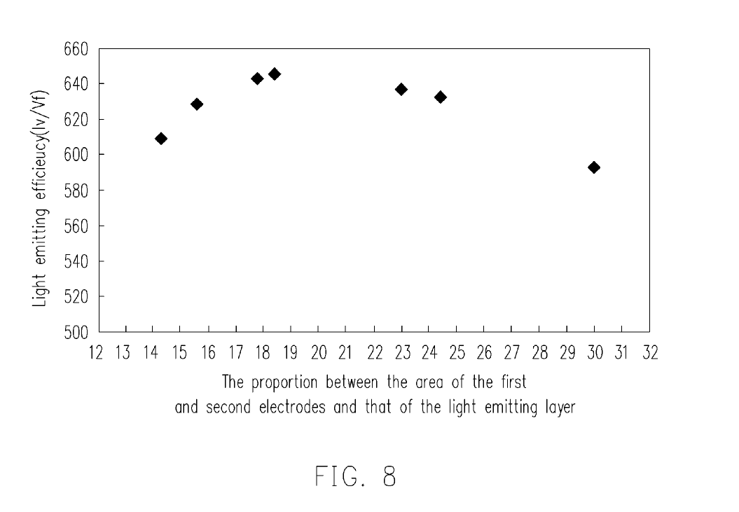

Under the conditions that the area of the light emitting device is 1×10⁶ μm², the distance between the first electrode and the second electrode is 166 μm, and the area of the first electrode and the second electrode is 14.3%, 15.6%, 17.8%, 18.4%, 23%, 24.4% or 30% of that of the light emitting layer, and a relationship between the proportion of the area of the first and second electrode to that of the light emitting layer and the light emitting efficiency of the semiconductor light emitting device is shown in FIG. 8. The light emitting efficiency of the semiconductor light emitting device is better if the proportions of the area of the first and second electrodes to that of the light emitting layer is about 15% to 25%. Furthermore, the light emitting efficiency of the semiconductor light emitting device is optimum if the proportion of the area of the electrodes to that of the light emitting layer is about 17% to 24.4%.

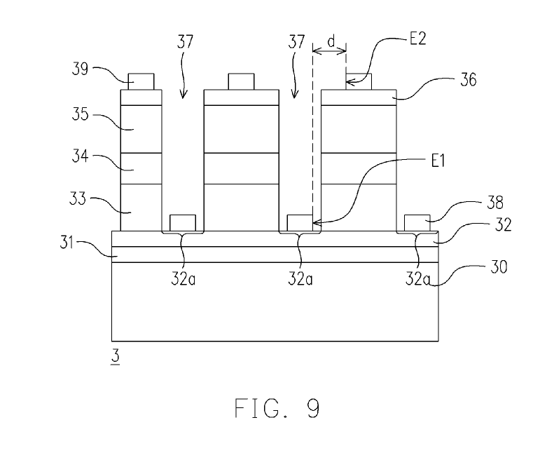

FIG. 9 is a schematic cross-sectional view illustrating a semiconductor light emitting device according to a third embodiment of the present invention. The semiconductor light emitting device 3 comprises a substrate 30, an adhesive layer 31, a light emitting stack, a spiral groove 37, a first electrode 38 and a second electrode 39. The adhesive layer 31 is disposed on the substrate 30 for adhering to a light emitting stack comprising a first transparent oxide conductive layer 32, a first AlInGaP based semiconductor stack 33, a light emitting layer 34, a second AlInGaP based semiconductor stack 35 and a second transparent oxide conductive layer 36. In one embodiment of the present invention, the adhesive layer 31 comprises at least one material selected from the group consisting of polyimide, benzocyclobutene (BCB), prefluorocyclobutane (PFCB), indium tin oxide, In, Sn, Al, Au, Pt, Zn, Ag, Ti, Pb, Ni, Au—Be, Au—Sn, Au—Si, Pb—Sn, Au—Ge, PdIn, and AuZn.

The first transparent oxide conductive layer 32 is disposed on the adhesive layer 31, and it comprises at least one material selected from the group consisting of indium tin oxide, cadmium tin oxide, antimony tin oxide, aluminum tin oxide and zinc tin oxide. The first AlInGaP based semiconductor stack 33 is disposed on the first transparent oxide conductive layer 32. The light emitting layer 34 is disposed on the first AlInGaP based semiconductor stack 33. The second AlInGaP based semiconductor stack 35 is disposed on the light emitting layer 34. The second transparent oxide conductive layer 36 is disposed on the second AlInGaP based semiconductor stack 35, and it comprises at least one material selected from the group consisting of indium tin oxide, cadmium tin oxide, antimony tin oxide, aluminum tin oxide and zinc tin oxide. The spiral groove 37 is formed in the second transparent oxide conductive layer 36, the second AlInGaP based semiconductor stack 35, the light emitting layer 34 and the first AlInGaP based semiconductor stack 33, to expose a portion of the first transparent oxide conductive layer 32 and form a first electrode region 32a. The first electrode 38 is disposed on the first electrode region 32a. The second electrode 39 is disposed on the second transparent oxide conductive layer 36. The top view of the semiconductor light emitting device 3 is similar to that of the semiconductor light emitting device 2.

Under the conditions that the area of the light emitting device is 5.6×10⁵ μm² (750 μm×750 μm), the input current is 350 mA, and the area of the first electrode 38 and the second electrode 39 is 24.4% of that of the light emitting layer 34, if the distance between the first edge E1 of the first electrode 38 and the second edge E2 of the second electrode 39 is 130 μm or 166 μm, the light emitting power of the light emitting device will be 58.35 mW or 67.47 mW accordingly. Under the condition that the input current is 400 mA, if the distance between the first electrode 38 and the second electrode 39 is 130 μm or 166 μm, the light emitting power will be 66.03 mW or 76.33 mW accordingly. Under the condition that the input current is 600 mA, if the distance between the first electrode 38 and the second electrode 39 is 130 μm or 166 μm, the light emitting power will be 93.18 mW or 100.87 mW accordingly. According to the above data, the light emitting power of the light emitting device of which the distance between the electrodes is 166 μm is better than that of the light emitting device of which the distance between the electrodes is 130 μm.

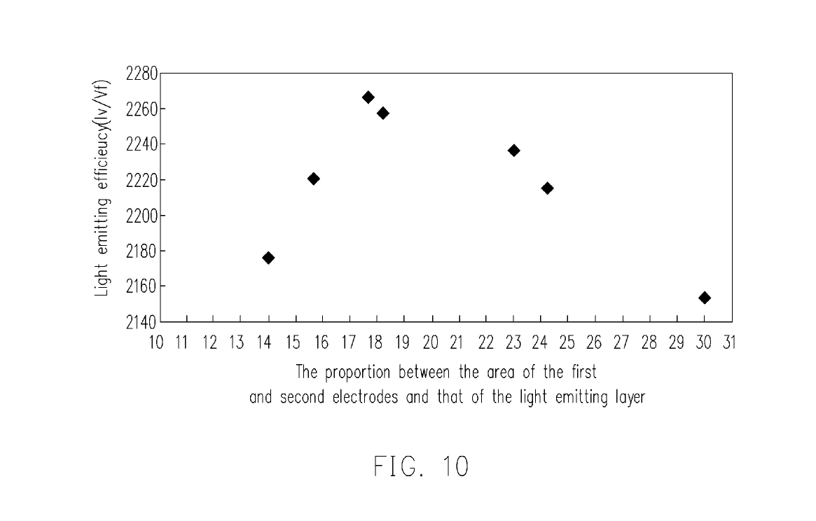

FIG. 10 is a diagram illustrating a relationship of the proportion of the area of the first and second electrode to that of the light emitting layer and the light emitting efficiency of the semiconductor light emitting device. Under the conditions that the area of the light emitting device is 5.6×10⁵ μm², the distance between the first electrode and the second electrode is 166 μm, and the area of the first electrode and the second electrode is 14.3%, 15.6%, 17.8%, 18.4%, 23%, 24.4%, or 30% of that of the light emitting layer, the light emitting efficiency of the light emitting device is better if the area of the first electrode and the second electrode is 15%˜25% of that of the light emitting layer. Furthermore, the light emitting efficiency of the light emitting device is optimum if the area of the first electrode and the second electrode is 17%˜18.4% of that of the light emitting layer.

The present invention is suitable for being applied to light emitting devices of middle input power (about 0.3W) and of which the area of the light emitting layer is 2.56×10⁵ μm², and light emitting devices of large input power (larger than 1 W) and of which the area of the light emitting layer is larger than 1×10⁶ μm².

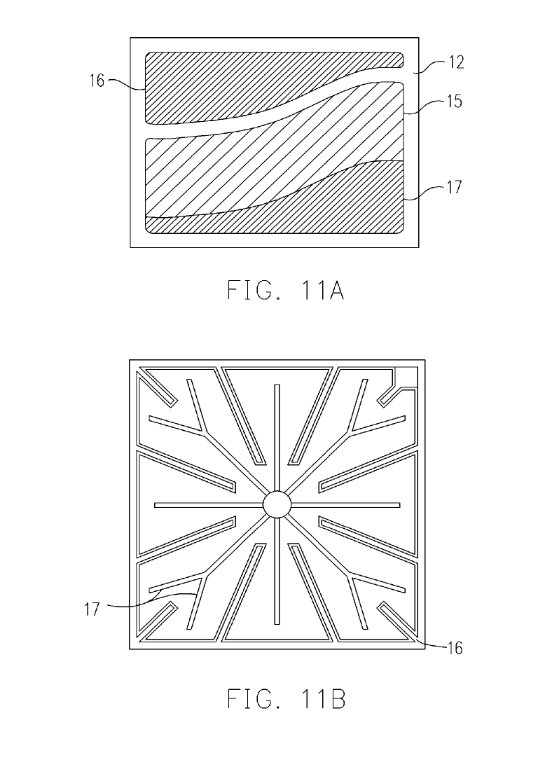

FIG. 11A and FIG. 11B are schematic top views illustrating different arrangement of the first electrode and the second electrode. Please refer to FIG. 11A and FIG. 11B, the shape of the first electrode 16 and the second electrode 17 can be plane shape or arborization.

Besides, in one embodiment of the present invention, the semiconductor light emitting device further comprises a first reactive layer disposed between the substrate and the adhesive layer. The first reactive layer comprises at least one material selected from the group consisting of SiNx, titanium, and chromium.

In one embodiment of the present invention, the semiconductor light emitting device further comprises a reflective layer disposed between the substrate and the first reactive layer. The reflective layer comprises at least one material selected from the group consisting of In, Sn, Al, Pt, Zn, Ag, Ti, Pb, Pd, Ge, Cu, AuBe, AuGe, Ni, PbSn, and AuZn.

In one embodiment of the present invention, the semiconductor light emitting device further comprises a second reactive layer disposed between the light emitting stack and the adhesive layer. The second reactive layer comprises at least one material selected from the group consisting of SiNx, titanium, and chromium.

In one embodiment of the present invention, the semiconductor light emitting device further comprises a reflective layer disposed between the light emitting stack and the second reactive layer. The reflective layer comprises at least one material selected from the group consisting of In, Sn, Al, Pt, Zn, Ag, Ti, Pb, Pd, Ge, Cu, AuBe, AuGe, Ni, PbSn, and AuZn.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

What is claimed is:

1. A semiconductor light emitting device, comprising:
a substrate;
a semiconductor light emitting stack disposed on the substrate having a first surface region and a second surface region, the semiconductor light emitting stack comprising:
a first semiconductor layer disposed on the substrate;
a light emitting layer disposed on the first semiconductor layer;
a second semiconductor layer disposed on the light emitting layer;
a first electrode disposed on the first surface region;
a first transparent oxide conductive layer disposed on the second surface region; and
a second electrode disposed on the first transparent oxide conductive layer, wherein the area of the light emitting device is larger than 2.5×10⁵ μm², the distance between a first edge of the first electrode and a second edge of the second electrode adjacent to the first edge is between 150 μm and 250 μm essentially, and the area of the first electrode and the second electrode is 15%˜25% of that of the light emitting layer.

2. The semiconductor light emitting device according to claim 1, further comprising an adhesive layer disposed between the substrate and the semiconductor light emitting stack.

3. The semiconductor light emitting device according to claim 2, wherein the adhesive layer comprises at least one material selected from the group consisting of polyimide, benzocyclobutene (BCB), prefluorocyclobutane (PFCB), indium tin oxide, In, Sn, Al, Au, Pt, Zn, Ag, Ti, Pb, Ni, Au—Be, Au—Sn, Au—Si, Pb—Sn, Au—Ge, PdIn, and AuZn.

4. The semiconductor light emitting device according to claim 2, further comprising a reactive layer disposed on one of the substrate and the adhesive layer.

5. The semiconductor light emitting device according to claim 4, wherein the reactive layer comprises at least one material selected from the group consisting of SiNx, titanium, and chromium.

6. The semiconductor light emitting device according to claim 4, further comprising a reflective layer disposed under one of the light emitting stack and the reactive layer.

7. The semiconductor light emitting device according to claim 6, wherein the reflective layer comprises at least one material selected from the group consisting of In, Sn, Al, Pt, Zn, Ag, Ti, Pb, Pd, Ge, Cu, AuBe, AuGe, Ni, PbSn, and AuZn.

8. The semiconductor light emitting device according to claim 1, wherein the second surface region of the semiconductor light emitting stack is a highly doped p-type semiconductor contact region, a reverse tunnel region or a surface roughed region.

9. The semiconductor light emitting device according to claim 1, wherein the first semiconductor layer comprises at least one material selected from the group consisting of AlN, GaN, AlGaN, InGaN, AlInGaN, GaP, GaAsP, GaInP, AlGaInP, and AlGaAs.

10. The semiconductor light emitting device according to claim 1, wherein the second semiconductor layer comprises at least one material selected from the group consisting of AlN, GaN, AlGaN, InGaN, AlInGaN, GaP, GaAsP, GaInP, AlGaInP, and AlGaAs.

11. The semiconductor light emitting device according to claim 1, wherein the shape of the first electrode comprises spiral shape, plane shape, and arborization.

12. The semiconductor light emitting device according to claim 1, wherein the shape of the second electrode comprises spiral shape, plane shape, and arborization.

13. The semiconductor light emitting device according to claim 1, wherein the first transparent oxide conductive layer comprises at least one material selected from the group consisting of indium tin oxide, cadmium tin oxide, antimony tin oxide, aluminum tin oxide, and zinc tin oxide.

14. The semiconductor light emitting device according to claim 1, further comprising a second transparent oxide conductive layer disposed between the substrate and the semiconductor light emitting stack.

15. The semiconductor light emitting device according to claim 14, wherein the second transparent oxide conductive layer comprises at least one material selected from the group consisting of indium tin oxide, cadmium tin oxide, antimony tin oxide, aluminum tin oxide, and zinc tin oxide.

16. The semiconductor light emitting device according to claim 15, wherein the first surface region is extended to the second transparent oxide conductive layer.
